(19) United States
(12) Patent Application Publication
(10) Pub. No.: US 2026/0128731 A1
(43) Pub. Date: May 7, 2026

(54) ACOUSTIC WAVE FILTER DEVICE

(71) Applicant: Murata Manufacturing Co., Ltd., Nagaokakyo-shi (JP)

(72) Inventors: Eiji FUJIMORI, Nagaokakyo-shi (JP); Mitsuyuki TANAKA, Nagaokakyo-shi (JP)

(21) Appl. No.: 19/441,001

(22) Filed: Jan. 6, 2026

Related U.S. Application Data
(63) Continuation of application No. PCT/JP2024/028211, filed on Aug. 7, 2024.

(30) Foreign Application Priority Data
Aug. 28, 2023 (JP) 2023-137753

(51) Int. Cl. H03H 9/56; H03H 9/13; H03H 9/205

(52) U.S. Cl. CPC H03H 9/568; H03H 9/133; H03H 9/205

(57) ABSTRACT

An acoustic wave filter device includes a series-arm resonator connected between an input terminal and an output terminal, a parallel-arm resonator connected between a ground terminal and a node on a path connecting the input terminal and the output terminal, and a capacitor connected between the input terminal and the output terminal. The capacitor is connected in parallel to the series-arm resonator. The acoustic wave filter device includes series-arm resonators. The capacitor is connected in parallel to the series-arm resonator connected to the input terminal of the series-arm resonators.

### CROSS REFERENCE TO RELATED APPLICATIONS

This application claims the benefit of priority to Japanese Patent Application No. 2023-137753 filed on Aug. 28, 2023 and is a Continuation application of PCT Application No. PCT/JP2024/028211 filed on Aug. 7, 2024. The entire contents of each application are hereby incorporated herein by reference.

### BACKGROUND OF THE INVENTION

### 1. Field of the Invention

The present invention relates to acoustic wave filter devices.

### 2. Description of the Related Art

International Publication No. 2017/110308, Japanese Unexamined Patent Application Publication No. 2016-152612, and Japanese Unexamined Patent Application Publication No. 2010-526456 describe acoustic wave devices (an electrical component in Japanese Unexamined Patent Application Publication No. 2010-526456) including a surface acoustic wave (SAW) element using a surface acoustic wave or a bulk acoustic wave (BAW) element using a bulk wave. For example, International Publication No. 2017/110308 discloses a configuration of the acoustic wave device in which an LC circuit is provided on a cover member.

Such an acoustic wave device is required to be reduced in size and to satisfactorily adjust the bandpass characteristic.

### SUMMARY OF THE INVENTION

Example embodiments of the present invention provide acoustic wave filter devices each with a reduced size and that are each able to satisfactorily adjust a bandpass characteristic.

An acoustic wave filter device according to an example embodiment of the present invention includes a series-arm resonator connected between an input terminal and an output terminal, a parallel-arm resonator connected between a ground terminal and a node on a path connecting the input terminal and the output terminal, and a capacitor connected between the input terminal and the output terminal, the capacitor being connected in parallel to the series-arm resonator.

The acoustic wave filter devices according to example embodiments of the present invention are each reduced in size and are each able to satisfactorily adjust the bandpass characteristic.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram illustrating an acoustic wave filter device according to Example Embodiment 1 of the present invention.

FIG. 2 is a plan view illustrating the acoustic wave filter device according to Example Embodiment 1 of the present invention.

FIG. 3 is a plan view illustrating a portion of the acoustic wave filter device according to Example Embodiment 1 of the present invention.

FIG. 4 is a sectional view taken along IV-IV′ in FIG. 3.

FIG. 5 is a graph schematically illustrating the bandpass characteristics of acoustic wave filter devices according to an example and a comparative example.

FIG. 6 is a graph schematically illustrating the impedance characteristics of series-arm resonators and parallel-arm resonators according to an example of an example embodiment of the present invention and a comparative example.

FIG. 7 is a plan view illustrating an acoustic wave filter device according to Example Embodiment 2 of the present invention.

FIG. 8 is a sectional view illustrating the acoustic wave filter device according to Example Embodiment 2 of the present invention.

FIG. 9 is a plan view illustrating a portion of an acoustic wave filter device according to Example Embodiment 3 of the present invention.

FIG. 10 is a sectional view taken along X-X′ in FIG. 9.

FIG. 11 is a plan view illustrating a portion of an acoustic wave filter device according to a modified example of Example Embodiment 3 of the present invention.

FIG. 12 is a sectional view illustrating an acoustic wave filter device according to Example Embodiment 4 of the present invention.

### DETAILED DESCRIPTION OF THE EXAMPLE EMBODIMENTS

Example embodiments of the present invention will be described in detail below with reference to the drawings. The present invention is not limited by the example embodiments. The embodiments described in the present disclosure are merely examples, and the configurations of different example embodiments can be partially replaced or combined. From Example Embodiment 2 and in a modified example, points in common with Example Embodiment 1 are not described, and only different points are described. In particular, the same or similar advantageous effects resulting from the same or similar configurations are not described in each example embodiment.

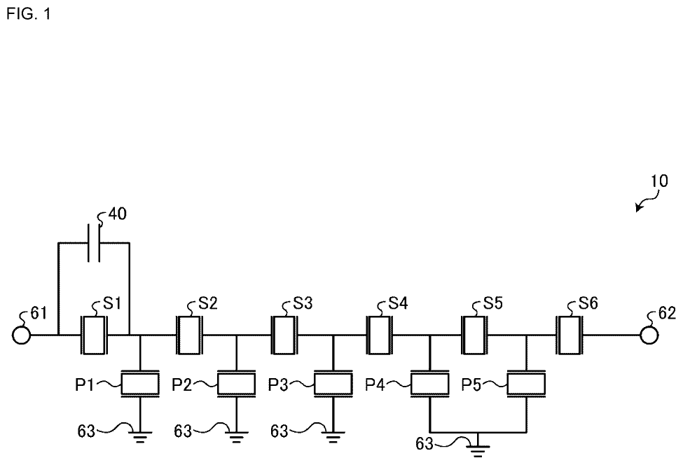

FIG. 1 is a circuit diagram illustrating an acoustic wave filter device according to Example Embodiment 1 of the present invention. Resonators of an acoustic wave filter device 10 according to Example Embodiment 1 are resonators using bulk waves, that is, bulk acoustic wave (BAW) elements, for example.

As illustrated in FIG. 1, the acoustic wave filter device 10 according to Example Embodiment 1 includes a plurality of series-arm resonators S1, S2, S3, S4, S5, and S6, a plurality of parallel-arm resonators P1, P2, P3, P4, and P5, and a capacitor 40. The plurality of series-arm resonators S1, S2, S3, S4, S5, and S6 are connected in series to the signal path between an input terminal 61 and an output terminal 62. The plurality of parallel-arm resonators P1, P2, P3, P4, and P5 are connected in parallel between ground terminals 63 and nodes on the signal path connecting the input terminal 61 and the output terminal 62. The acoustic wave filter device 10 according to Example Embodiment 1 is a ladder filter.

One terminal of each of the plurality of series-arm resonators S1, S2, S3, S4, S5, and S6 connected in series is electrically connected to the input terminal 61, and the other terminal of each of the plurality of series-arm resonators S1, S2, S3, S4, S5, and S6 connected in series is electrically connected to the output terminal 62. One terminal of the parallel-arm resonator P1 is electrically connected to the node on the signal path connecting the series-arm resonator S1 and the series-arm resonator S2, and the other terminal of the parallel-arm resonator P1 is electrically connected to the ground terminal 63. One terminal of the parallel-arm resonator P2 is electrically connected to the node on the signal path connecting the series-arm resonator S2 and the series-arm resonator S3, and the other terminal of the parallel-arm resonator P2 is electrically connected to the ground terminal 63.

One terminal of the parallel-arm resonator P3 is electrically connected to the node on the signal path connecting the series-arm resonator S3 and the series-arm resonator S4, and the other terminal of the parallel-arm resonator P3 is electrically connected to the ground terminal 63. One terminal of the parallel-arm resonator P4 is electrically connected to the node on the signal path connecting the series-arm resonator S4 and the series-arm resonator S5, and the other terminal of the parallel-arm resonator P4 is electrically connected to the ground terminal 63. One terminal of the parallel-arm resonator P5 is electrically connected to the node on the signal path connecting the series-arm resonator S5 and the series-arm resonator S6, and the other terminal of the parallel-arm resonator P5 is electrically connected to the ground terminal 63.

The capacitor 40 is connected in parallel to the series-arm resonator S1. That is, the capacitor 40 is connected between the input terminal 61 and the output terminal 62 and is connected in parallel to the series-arm resonator S1. More specifically, one end side of the capacitor 40 is electrically connected to the node on the signal path connecting the input terminal 61 and the series-arm resonator S1. The other end side of the capacitor 40 is electrically connected to the node on the signal path connecting the series-arm resonator S1 and the series-arm resonator S2.

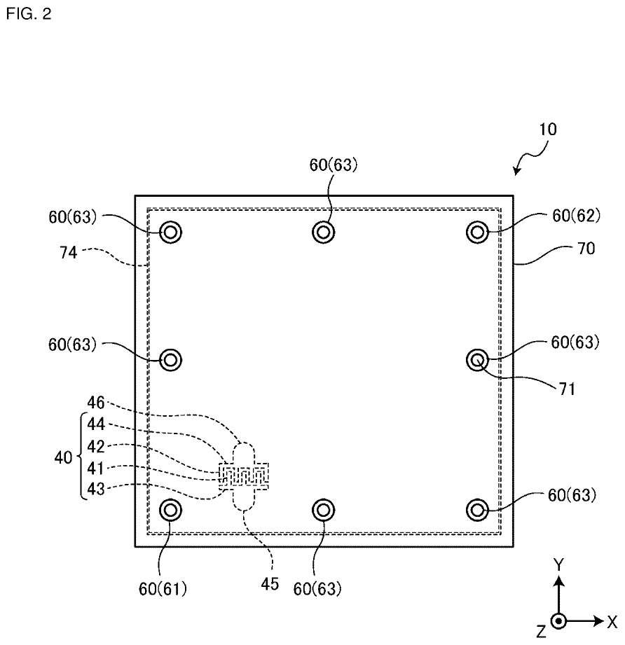

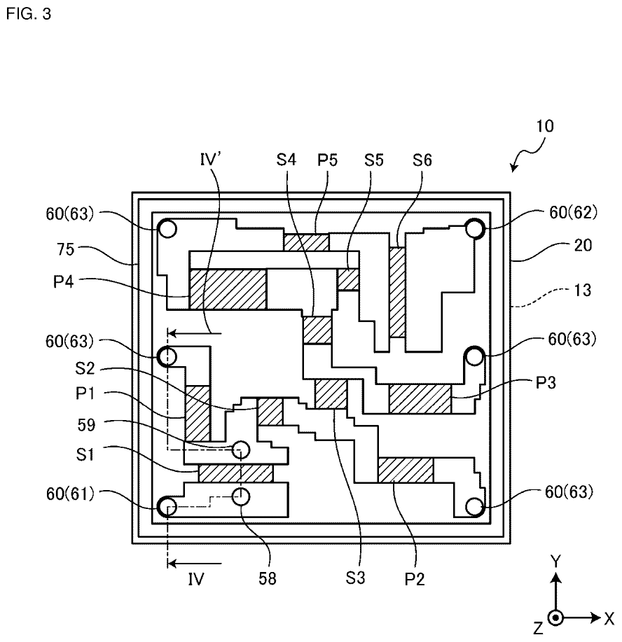

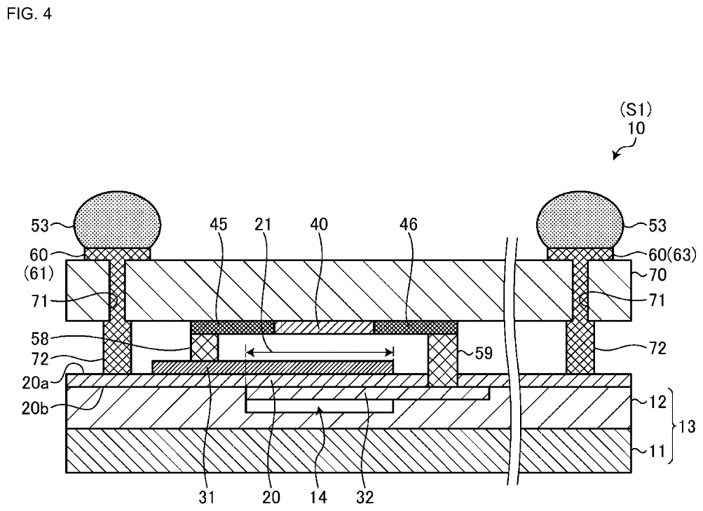

Next, a configuration example of the acoustic wave filter device 10 according to Example Embodiment 1 will be described with reference to FIGS. 2 to 4. FIG. 2 is a plan view illustrating the acoustic wave filter device according to Example Embodiment 1. FIG. 3 is a plan view illustrating a portion of the acoustic wave filter device according to Example Embodiment 1. FIG. 4 is a sectional view taken along IV-IV′ in FIG. 3. FIG. 3 is a plan view illustrating the acoustic wave filter device 10 according to Example Embodiment 1 excluding a cover portion 70. To make FIG. 3 easier to view, FIG. 3 illustrates the plurality of series-arm resonators S1, S2, S3, S4, S5, and S6, and the plurality of parallel-arm resonators P1, P2, P3, P4, and P5 with hatching lines.

As illustrated in FIGS. 2 to 4, the acoustic wave filter device 10 includes a support 13, a piezoelectric layer 20, an upper electrode 31, and a lower electrode 32. The acoustic wave filter device 10 further includes the cover portion 70 provided above the resonators, the capacitor 40, interelement connection electrodes 58 and 59, terminals 60, bumps 53, vias 71, connectors 72, and sealing portions 74 and 75.

In the following description, the thickness direction of the piezoelectric layer 20 is the Z direction, a direction orthogonal or substantially orthogonal to the Z direction is the X direction, and a direction orthogonal or substantially orthogonal to the Z direction and the X direction is the Y direction. The X direction and the Y direction are respective directions parallel or substantially parallel to a surface (first main surface 20a) of the piezoelectric layer 20. In addition, in the following description, the term “plan view” means a view for illustrating the arrangement relationship when components are viewed in a direction (Z direction) perpendicular or substantially perpendicular to the first main surface 20a of the piezoelectric layer 20.

As illustrated in FIG. 2, the plurality of terminals 60 (the input terminal 61, the output terminal 62, and the plurality of ground terminals 63) of the acoustic wave filter device 10 are provided on an upper surface of the cover portion 70. The input terminal 61 of the plurality of terminals 60 is located at the lower left of the cover portion 70. The output terminal 62 of the plurality of terminals 60 is located at the upper right of the cover portion 70. The terminals 60 other than the input terminal 61 and the output terminal 62 are the ground terminals 63. In addition, the capacitor 40 is provided, at a position overlapping the series-arm resonator S1 (see FIG. 3), on the surface (lower surface) of the cover portion 70 facing the support 13.

As illustrated in FIG. 3, the plurality of series-arm resonators S1, S2, S3, S4, S5, and S6, and the plurality of parallel-arm resonators P1, P2, P3, P4, and P5 of the acoustic wave filter device 10 are provided on the support 13. In the following description, when the plurality of series-arm resonators S1, S2, S3, S4, S5, and S6, and the plurality of parallel-arm resonators P1, P2, P3, P4, and P5 do not have to be distinguished from each other, these resonators are simply referred to as resonators.

The respective resonators are electrically connected to the respective terminals 60 on the cover portion 70 via the nodes on the signal path formed on the support 13, the connectors 72, and the vias 71 (see FIG. 4).

As illustrated in FIGS. 2 and 3, the sealing portion 74 is provided at the outer edge of the cover portion 70. In addition, the sealing portion 75 is provided at the outer edge of the support 13. The sealing portions 74 and 75 are each provided in a frame shape so as to surround the plurality of resonators and the plurality of terminals 60 in plan view. The cover portion 70 and the support 13 are disposed so as to face each other, and the sealing portion 74 and the sealing portion 75 are connected so as to overlap each other, thus sealing the space surrounded by the cover portion 70, the support 13, the sealing portion 74, and the sealing portion 75.

The arrangement of the plurality of resonators, the plurality of terminals 60, and various wiring lines connecting these components illustrated in FIGS. 2 and 3 is merely an example and can be changed as appropriate. For example, the plurality of terminals 60 are arranged along the outer edge of the cover portion 70, but the configuration is not limited thereto. The plurality of terminals 60 may be provided on a central portion of the cover portion 70.

Next, the multilayer structure of the acoustic wave filter device 10 will be described with reference to FIG. 4. FIG. 4 illustrates the multilayer structure of the series-arm resonator S1 of the plurality of resonators. However, the descriptions of the series-arm resonator S1 excluding the structure provided by the capacitor 40 and the interelement connection electrodes 58 and 59 in FIG. 4 can also be applied to the other resonators.

As illustrated in FIG. 4, the lower electrode 32, the piezoelectric layer 20, and the upper electrode 31 are laminated in this order on the support 13 to define the series-arm resonator S1.

The support 13 is provided so as to face a second main surface 20b of the piezoelectric layer 20. The support 13 includes a support substrate 11 and an insulating layer 12. The support substrate 11 is made of, for example, silicon (Si) or quartz crystal. The insulating layer 12 is provided between the support substrate 11 and the piezoelectric layer 20. The insulating layer 12 is made of an insulating material such as, for example, silicon oxide. The support 13 may be configured such that the piezoelectric layer 20 is provided on the support substrate 11 without the insulating layer 12.

The surface of the support 13 (insulating layer 12) facing the second main surface 20b of the piezoelectric layer 20 includes a cavity portion 14 (hollow portion). The cavity portion 14 is provided so as to overlap an excitation region 21 of the resonator provided by stacking the piezoelectric layer 20, the upper electrode 31, and the lower electrode 32 in plan view. Thus, a bulk wave is reflected by the cavity portion 14.

The piezoelectric layer 20 is a flat layer including the first main surface 20a and the second main surface 20b opposite to the first main surface 20a. The piezoelectric layer 20 is a substrate made of, for example, a single crystal of lithium niobate (LiNbO₃) or lithium tantalate (LiTaO₃). The thickness of the piezoelectric layer 20 is not particularly limited and is preferably, for example, about 1 μm or less.

The upper electrode 31 is provided on the first main surface 20a of the piezoelectric layer 20. The upper electrode 31 includes a portion overlapping the cavity portion 14 of the insulating layer 12, and a portion extending outward of the cavity portion 14.

The lower electrode 32 is provided on the second main surface 20b of the piezoelectric layer 20. At least a portion of the lower electrode 32 is provided in a region overlapping the upper electrode 31. The lower electrode 32 includes a portion overlapping the cavity portion 14 and the upper electrode 31, and a portion that does not overlap the cavity portion 14 and the upper electrode 31 and that extends outward of the cavity portion 14. In addition, an adhesion layer made of, for example, Ti or NiCr may be located between the lower electrode 32 and the insulating layer 12.

The acoustic wave filter device 10 has a membrane structure in which the cavity portion 14 (hollow portion) is provided on the second main surface 20b side of the piezoelectric layer 20. The piezoelectric layer 20 is disposed between the upper electrode 31 and the lower electrode 32 in the Z direction in a region overlapping the cavity portion 14. Thus, a bulk wave is propagated between the upper electrode 31 and the lower electrode 32. In the following description, the region where the upper electrode 31 and the lower electrode 32 overlap each other in plan view may be the excitation region 21 of the resonator.

Although not illustrated in FIG. 4, for example, the portion (wiring portion) of the upper electrode 31 extending outward of the cavity portion 14 is electrically connected to the input terminal 61, and the portion (wiring portion) of the lower electrode 32 extending outward of the cavity portion 14 is electrically connected to the series-arm resonator S2 and the parallel-arm resonator P1. The configuration is not limited thereto, and the configuration in which the upper electrode 31 is electrically connected to the series-arm resonator S2 and the parallel-arm resonator P1 and the lower electrode 32 is electrically connected to the input terminal 61 may be provided.

The upper electrode 31 and the lower electrode 32 are made of a metal such as, for example, aluminum (Al), platinum (Pt), copper (Cu), tungsten (W), or molybdenum (Mo) or an alloy including at least one of these materials. The upper electrode 31 and the lower electrode 32 may each be a multilayer film.

The cover portion 70 is disposed so as to face the first main surface 20a of the piezoelectric layer 20. The connectors 72 are provided between the cover portion 70 and the first main surface 20a of the piezoelectric layer 20. The cover portion 70 is made of the same material as the material for the support substrate 11, for example, and is made of, for example, silicon (Si) or quartz crystal. In addition, the plurality of terminals 60 and bumps 53 are provided on the upper surface (side opposite to the surface facing the first main surface 20a of the piezoelectric layer 20) of the cover portion 70.

One of the upper electrode 31 and the lower electrode 32 of the series-arm resonator S1 is electrically connected to the input terminal 61 provided on the upper surface of the cover portion 70 via the connector 72 and the via 71 passing through the cover portion 70.

The capacitor 40 is provided on the surface of the cover portion 70 facing the first main surface 20a of the piezoelectric layer 20. The capacitor 40 is disposed in a region overlapping the excitation region 21 of the series-arm resonator S1.

As illustrated in FIG. 2, the capacitor 40 has a flat shape and includes an interdigital transducer (IDT) electrode. The capacitor 40 includes electrode fingers 41 and 42, and busbar electrodes 43 and 44. The plurality of electrode fingers 41 extend in the Y direction, and the one end of each of the plurality of electrode fingers 41 in the extending direction is connected to the busbar electrode 43. The plurality of electrode fingers 42 extend in the Y direction, and the other end of each of the plurality of electrode fingers 42 in the extending direction is connected to the busbar electrode 44. The plurality of electrode fingers 41 and the plurality of electrode fingers 42 are alternately arranged in the X direction so as to be spaced from each other. The busbar electrode 43 and the busbar electrode 44 extend in the X direction and are spaced away from each other in the Y direction. The plurality of electrode fingers 41 and 42 are arranged between the busbar electrode 43 and the busbar electrode 44. The capacitance of the capacitor 40 is generated between the plurality of electrode fingers 41 and the plurality of electrode fingers 42 disposed so as to be spaced away from each other.

A connection wiring line 45 is connected to the busbar electrode 43 of the capacitor 40. A connection wiring line 46 is connected to the busbar electrode 44 of the capacitor 40.

As illustrated in FIG. 4, the interelement connection electrodes 58 and 59 are provided between the support 13 and the cover portion 70. The interelement connection electrode 58 (first interelement connection electrode) electrically connects the upper electrode 31 and the connection wiring line 45 connected to the one end side of the capacitor 40. The interelement connection electrode 59 (second interelement connection electrode) electrically connects the lower electrode 32 and the connection wiring line 46 connected to the other end of the capacitor 40. More specifically, the interelement connection electrode 59 is connected to the lower electrode 32 through an opening provided in the piezoelectric layer 20.

With this configuration, the capacitor 40 is connected in parallel to the series-arm resonator S1 via the connection wiring lines 45 and 46 and the interelement connection electrodes 58 and 59. The connection wiring lines 45 and 46 are the same components as the wiring portions described above, and the material for the wiring portions can also be used for the connection wiring lines 45 and 46.

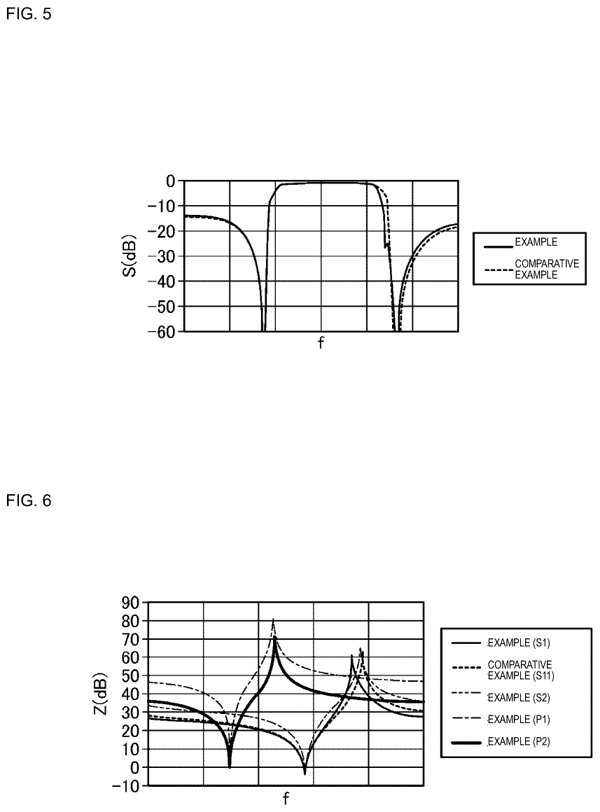

FIG. 5 is a graph schematically illustrating the bandpass characteristics of acoustic wave filter devices according to an example of an example embodiment of the present invention and a comparative example. FIG. 6 is a graph schematically illustrating the impedance characteristics of series-arm resonators and parallel-arm resonators according to the present example and the comparative example. FIG. 6 illustrates the respective impedance characteristics of the series-arm resonators and the parallel-arm resonators. In addition, the acoustic wave filter device according to the comparative example and the series-arm resonator according to the comparative example are an acoustic wave filter device and a series-arm resonator that are not provided with the capacitor 40, respectively.

The vertical axis of the graph illustrated in FIG. 5 represents the bandpass characteristic (S (Scattering) parameter S21 level (dB)). The vertical axis of the graph illustrated in FIG. 6 represents the impedance level (dB). The horizontal axis of each of the graphs illustrated in FIGS. 5 and 6 represents the frequency.

As illustrated in FIG. 6, since the capacitor 40 is connected in parallel to the series-arm resonator S1 according to the present example, the series-arm resonator S1 according to the present example is smaller in fractional bandwidth than a series-arm resonator S11 according to the comparative example. In addition, the attenuation pole of the series-arm resonator S1 according to the present example is shifted to the lower frequency side than that of the series-arm resonator S11 according to the comparative example.

In addition, the attenuation pole of the series-arm resonator S1 is located on the higher frequency side than that of each of the parallel-arm resonators P1 and P2, for example.

As illustrated in FIG. 5, since the capacitor 40 is connected in parallel to the series-arm resonator S1, the acoustic wave filter device 10 according to the present example is capable of adjusting the bandpass characteristic on the higher frequency side in the passband compared with the comparative example. In addition, the capacitor 40 is connected in parallel to the series-arm resonator S1 having the lowest frequency of the plurality of series-arm resonators S1, S2, S3, S4, S5, and S6. Thus, it is possible to satisfactorily adjust the bandpass characteristic on the higher frequency side.

In addition, as illustrated in FIG. 4, the capacitor 40 is provided on the cover portion 70 and is connected, by the interelement connection electrodes 58 and 59, to the series-arm resonator S1 provided on the support 13 side. Thus, it is possible to reduce the size of the acoustic wave filter device 10 compared with a configuration in which the capacitor 40 is provided on the support 13 side.

In other words, the capacitor 40 on the cover portion 70 eliminates the need for providing another disposition area for providing the capacitor 40 on the support 13 side. Thus, the acoustic wave filter device 10 is capable of adjusting the bandpass characteristic by providing the capacitor 40 while the element size of each resonator is maintained. In addition, the capacitor 40 is provided on the cover portion 70, and the cover portion 70 has a sufficient disposition area. Thus, it is possible to ensure sufficient flexibility in the shape and the disposition of the capacitor 40 and to thus add, to the series-arm resonator S1, a predetermined capacitance according to a required bandpass characteristic.

In addition, in such a resonator having a membrane structure, the heat generated in the excitation region 21 may be confined in the cavity portion 14. In the acoustic wave filter device 10 according to the present example embodiment, the capacitor 40 is connected to the series-arm resonator S1, thus providing a heat transfer path (first heat transfer path) from the upper electrode 31 to the cover portion 70 through the interelement connection electrode 58, the connection wiring line 45, and the capacitor 40. In addition, a heat transfer path (second heat transfer path) from the lower electrode 32 to the cover portion 70 through the interelement connection electrode 59, the connection wiring line 46, and the capacitor 40 is provided.

As described above, for example, silicon (Si) is used as a material for the cover portion 70. The cover portion 70 has a higher thermal conductivity than the insulating layer 12. Thus, the heat generated in the excitation region 21 is transferred to the cover portion 70 through the above two heat transfer paths and can be released to the outside. In addition, the interelement connection electrodes 58 and 59 defining the two heat transfer paths are provided at respective positions closer to the excitation region 21 than the connector 72. Thus, it is possible to efficiently transfer the heat generated in the excitation region 21 to the cover portion 70 side.

In addition, the capacitor 40 is provided so as to correspond to the series-arm resonator S1 connected to the input terminal 61, to which a signal is inputted, and closest to the input terminal 61 of the plurality of resonators. That is, the capacitor 40 is provided so as to correspond to the series-arm resonator S1, whose amount of heat generated is larger than the parallel-arm resonators P1, P2, P3, P4, and P5. Thus, it is possible to efficiently release the heat generated in the excitation region 21 to the outside.

The present example embodiment illustrates a configuration in which the capacitor 40 is provided so as to correspond to the one series-arm resonator S1, but the configuration is not limited thereto. The acoustic wave filter device 10 may include a plurality of the capacitors 40, and the respective capacitors 40 may be provided at two or more series-arm resonators of the plurality of series-arm resonators S1, S2, S3, S4, S5, and S6. Alternatively, the respective capacitors 40 may be provided at the parallel-arm resonators P1, P2, P3, P4, and P5 as appropriate.

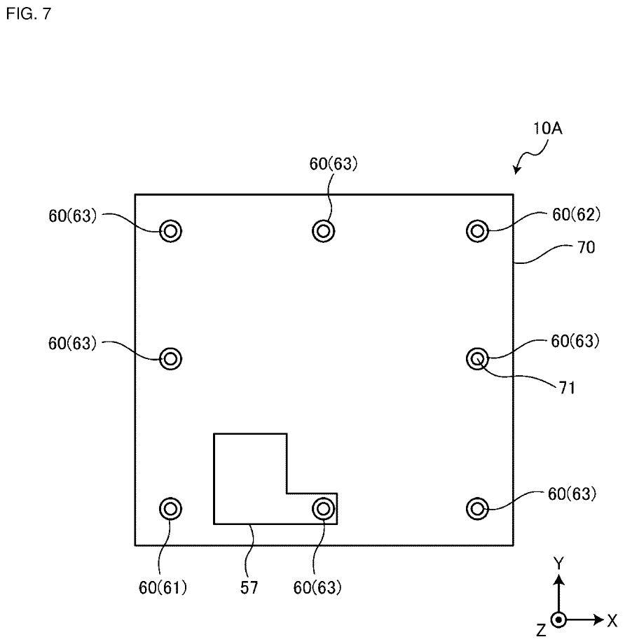

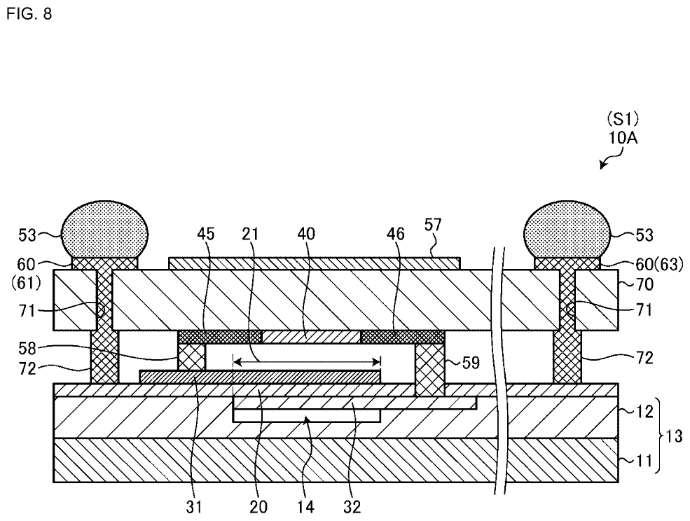

FIG. 7 is a plan view illustrating an acoustic wave filter device according to Example Embodiment 2 of the present invention. FIG. 8 is a sectional view illustrating the acoustic wave filter device according to Example Embodiment 2. As illustrated in FIGS. 7 and 8, an acoustic wave filter device 10A according to Example Embodiment 2 differs from Example Embodiment 1 described above in the configuration including a shield electrode 57.

The shield electrode 57 is provided on the upper surface (side opposite to the surface facing the first main surface 20a of the piezoelectric layer 20) of the cover portion 70 and is located in a region overlapping the capacitor 40. That is, the shield electrode 57 is provided so as to correspond to the series-arm resonator S1 of the plurality of resonators and is provided in a region overlapping the excitation region 21 of the series-arm resonator S1. The shield electrode 57 is connected to the ground terminal 63, and a reference potential (for example, a ground potential) is supplied thereto.

The shield electrode 57 reduces external noise that enters the capacitor 40 and the excitation region 21 from the cover portion 70 side. Thus, the acoustic wave filter device 10A is capable of reducing or preventing a deterioration in bandpass characteristic due to external noise.

In addition, the capacitor 40 and the shield electrode 57 are provided so as to at least correspond to the series-arm resonator S1 connected to the input terminal 61 of the plurality of series-arm resonators. Thus, the heat generated in the excitation region 21 is transferred to the cover portion 70 through the above two heat transfer paths and is efficiently released to the outside by the shield electrode 57. In this case, the shield electrode 57 is preferably made of a material having a higher thermal conductivity than the cover portion 70.

The shield electrode 57 is connected to the independent ground terminal 63 (ground terminal 63 not connected to the other resonators). However, the configuration is not limited thereto, and the shield electrode 57 may be connected to the ground terminal 63 common to other resonators. In addition, the shield electrode 57 has a rectangular or substantially rectangular shape in plan view, but the shape is not limited thereto, and may have a different shape such as a polygonal shape or a circular shape, for example.

Example Embodiment 2 illustrates a configuration in which the capacitor 40 and the shield electrode 57 are provided so as to correspond to the one series-arm resonator S1, but the configuration is not limited thereto. The acoustic wave filter device 10A may include a plurality of the capacitors 40 and a plurality of the shield electrodes 57, and the respective capacitors 40 and shield electrodes 57 may be provided at two or more series-arm resonators of the plurality of series-arm resonators S1, S2, S3, S4, S5, and S6. Alternatively, the respective capacitors 40 and shield electrodes 57 may be provided at the parallel-arm resonators P1, P2, P3, P4, and P5 as appropriate.

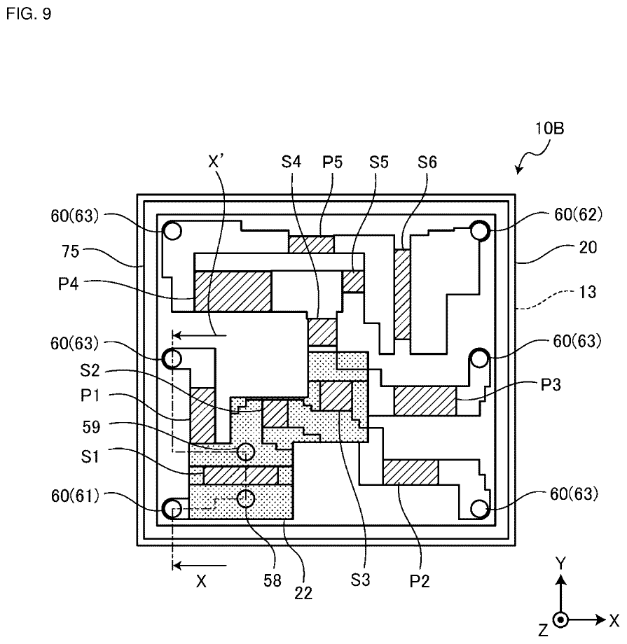

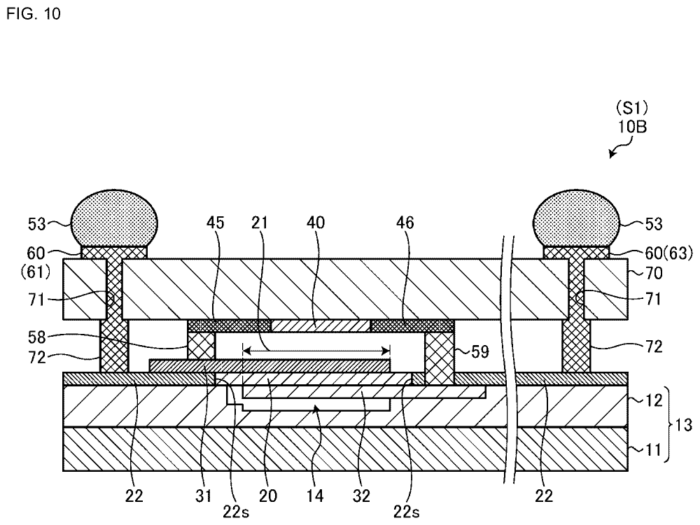

FIG. 9 is a plan view illustrating a portion of an acoustic wave filter device according to Example Embodiment 3 of the present invention. FIG. 10 is a sectional view taken along X-X′ in FIG. 9. As illustrated in FIGS. 9 and 10, an acoustic wave filter device 10B according to Example Embodiment 3 differs from Example Embodiment 1 described above in the configuration including a highly thermal conductive layer 22.

As illustrated in FIG. 9, the highly thermal conductive layer 22 is provided so as to correspond to each of the series-arm resonators S1, S2, and S3 close to the input terminal 61 of the plurality of series-arm resonators. The highly thermal conductive layer 22 is provided around and close to the excitation region 21 of each of the series-arm resonators S1, S2, and S3.

FIG. 10 illustrates a sectional view of the series-arm resonator S1 of the plurality of series-arm resonators. However, respective sectional views of the series-arm resonators S2 and S3 are the same as or similar to the sectional view of the series-arm resonator S1, and the descriptions of the series-arm resonator S1 can also be applied to those of the series-arm resonators S2 and S3.

As illustrated in FIG. 10, the highly thermal conductive layer 22 is provided, in the same layer as the piezoelectric layer 20, on the insulating layer 12 of the support 13. The highly thermal conductive layer 22 has a thermal conductivity higher than the thermal conductivity of the piezoelectric layer 20. The highly thermal conductive layer 22 is made of a material such as, for example, beryllium oxide (BeO), aluminum nitride (AlN), silicon carbide (SiC), boron nitride (BN), or aluminum oxide (Al₂O₃). The highly thermal conductive layer 22 is not limited to a single layer and may be a multilayer film including a plurality of layers that are laminated.

Specifically, the thermal conductivity of lithium niobate (LiNbO₃) used as a material for the piezoelectric layer 20 is, for example, about 4.6 W/k/m, and the thermal conductivity of lithium tantalate (LiTaO₃) used as a material for the piezoelectric layer 20 is, for example, about 8.78 W/k/m. On the other hand, the thermal conductivity of beryllium oxide (Be) used as a material for the highly thermal conductive layer 22 described above is, for example, about 265 W/k/m. Alternatively, the thermal conductivity of aluminum nitride (AlN) is, for example, about 180 W/k/m. The thermal conductivity of silicon carbide (SiC) is, for example, about 70 W/k/m. The thermal conductivity of boron nitride (BN) is, for example, about 60 W/k/m. The thermal conductivity of aluminum oxide (Al₂O₃) is, for example, about 25 W/k/m.

The piezoelectric layer 20 is at least provided in a region overlapping the excitation region 21 in which the lower electrode 32 and the upper electrode 31 are laminated. The highly thermal conductive layer 22 is provided in a region around the excitation region 21. More specifically, the highly thermal conductive layer 22 is laminated on a portion of the lower electrode 32 that does not overlap the excitation region 21. In addition, the highly thermal conductive layer 22 is laminated on a portion of the upper electrode 31 that does not overlap the excitation region 21.

Side surfaces 22s of the highly thermal conductive layer 22, which are in contact with the piezoelectric layer 20, are provided close to the excitation region 21. The respective side surfaces 22s of the highly thermal conductive layer 22 are located between the interelement connection electrode 58 and the excitation region 21 and between the interelement connection electrode 59 and the excitation region 21. That is, the highly thermal conductive layer 22 is provided in a region overlapping the interelement connection electrode 58 (first interelement connection electrode) electrically connecting the upper electrode 31 and the connection wiring line 45 connected to the capacitor 40. In addition, the highly thermal conductive layer 22 is provided around the interelement connection electrode 59 (second interelement connection electrode) electrically connecting the lower electrode 32 and the connection wiring line 46 connected to the capacitor 40.

In addition, the highly thermal conductive layer 22 extends to a region overlapping the connector 72 disposed between the cover portion 70 and the support 13. The highly thermal conductive layer 22 at least extends to the position directly under the connector 72 and is connected to a lower portion of the connector 72. Thus, the highly thermal conductive layer 22 is connected, through the connector 72 and the via 71, to the bump 53 and the terminal 60 provided on the upper surface of the cover portion 70.

With this configuration, a heat transfer path (first heat transfer path) from the piezoelectric layer 20 in the excitation region 21 to the cover portion 70 through the left side of the highly thermal conductive layer 22 in FIG. 10, the upper electrode 31, the interelement connection electrode 58, the connection wiring line 45, and the capacitor 40 is provided. In addition, a heat transfer path (second heat transfer path) from the piezoelectric layer 20 in the excitation region 21 and the lower electrode 32 to the cover portion 70 through the right side of the highly thermal conductive layer 22 in FIG. 10, the interelement connection electrode 59, the connection wiring line 46, and the capacitor 40 is provided.

In addition, a heat transfer path (third heat transfer path) from the piezoelectric layer 20 in the excitation region 21 to the bump 53 through the left side of the highly thermal conductive layer 22 in FIG. 10, the connector 72, the via 71, and the terminal 60 (input terminal 61) is provided. In addition, a heat transfer path (fourth heat transfer path) from the piezoelectric layer 20 in the excitation region 21 and the lower electrode 32 to the bump 53 through the right side of the highly thermal conductive layer 22 in FIG. 10, the connector 72, the via 71, and the terminal 60 (ground terminal 63) is provided.

Thus, in the present example embodiment, the heat generated in the excitation region 21 is transferred to the upper surface side of the cover portion 70 through the four heat transfer paths and is satisfactorily released to the outside. Thus, the acoustic wave filter device 10B is capable of improving the dissipation of the heat generated in the excitation region 21.

As illustrated in FIG. 9, the highly thermal conductive layer 22 is provided at each of the series-arm resonators S1, S2, and S3 close to the input terminal 61 of the plurality of series-arm resonators, that is, the series-arm resonators S1, S2, and S3, whose amount of heat generated in the excitation region 21 is relatively large. Thus, the acoustic wave filter device 10B is capable of satisfactorily improving the heat dissipation of the whole resonators.

The present example embodiment may be combined with Example Embodiment 2 described above. That is, the configuration including the highly thermal conductive layer 22 provided around the excitation region 21, and the shield electrode 57 provided on the upper surface of the cover portion 70 may be provided. In this case, the acoustic wave filter device 10B is capable of further improving heat dissipation.

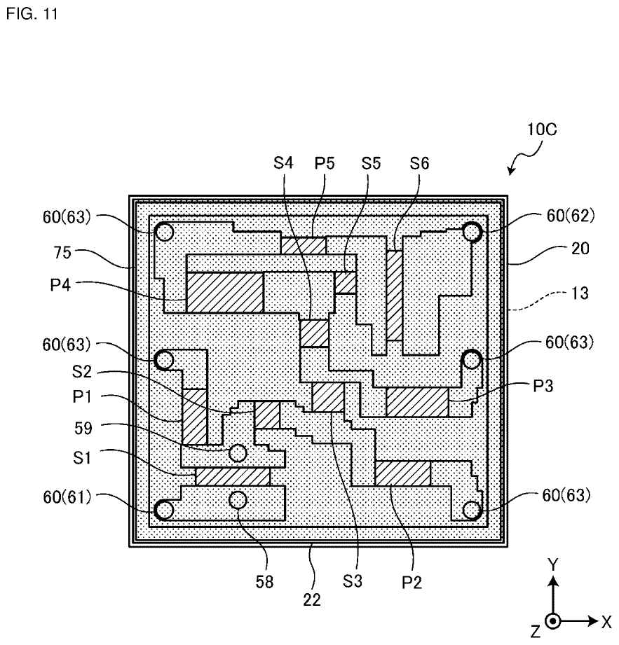

FIG. 11 is a plan view illustrating a portion of an acoustic wave filter device according to a modified example of Example Embodiment 3 of the present invention. As illustrated in FIG. 11, an acoustic wave filter device 10C according to the modified example of Example Embodiment 3 differs from Example Embodiment 3 described above in the configuration in which the highly thermal conductive layer 22 is provided at each of the plurality of series-arm resonators S1, S2, S3, S4, S5, and S6 and the plurality of parallel-arm resonators P1, P2, P3, P4, and P5.

More specifically, the highly thermal conductive layer 22 is provided around the excitation region 21 of each of the plurality of series-arm resonators S1, S2, S3, S4, S5, and S6 and the plurality of parallel-arm resonators P1, P2, P3, P4, and P5. In other words, the highly thermal conductive layer 22 is provided so as to cover the entire or substantially the entire surface of the support 13 excluding the excitation region 21 of each resonator.

Thus, in the present example embodiment, it is possible to improve the heat dissipation of each of the plurality of series-arm resonators S1, S2, S3, S4, S5, and S6 and the plurality of parallel-arm resonators P1, P2, P3, P4, and P5.

In FIGS. 9 to 11, the highly thermal conductive layer 22 is configured in disposition patterns so as to be continuous across a plurality of resonators. However, the disposition pattern of the highly thermal conductive layer 22 is not limited to the examples illustrated in FIGS. 9 to 11 described above and can be changed as appropriate. For example, a plurality of the highly thermal conductive layers 22 may be provided so as to be spaced apart from each other for each resonator or each plurality of resonators.

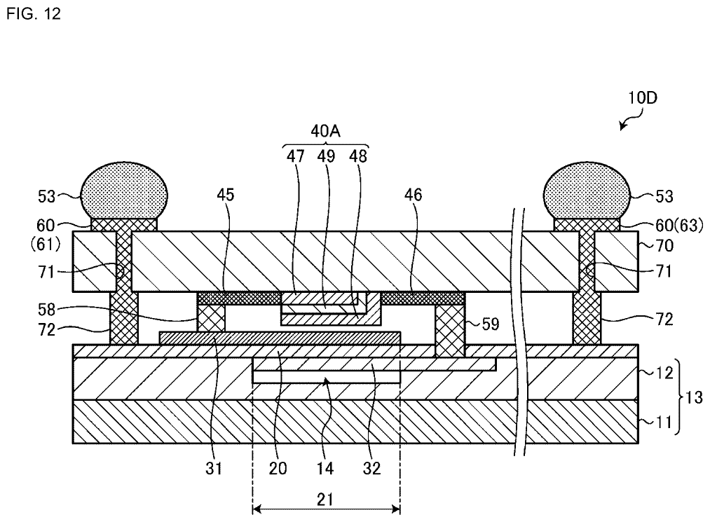

FIG. 12 is a sectional view illustrating an acoustic wave filter device according to Example Embodiment 4 of the present invention. As illustrated in FIG. 12, an acoustic wave filter device 10D according to Example Embodiment 4 differs from Example Embodiment 1 described above in the configuration including a multilayer capacitor 40A including multiple layers of electrodes.

The capacitor 40A includes a first electrode 47, a second electrode 48, and an insulating layer 49. The first electrode 47 is disposed so as to face the second electrode 48 with the insulating layer 49 interposed therebetween. The capacitor 40A is provided by laminating the first electrode 47, the insulating layer 49, and the second electrode 48 in this order on the surface (lower surface) of the cover portion 70 facing the support 13. That is, the capacitor 40A includes a parallel plate capacitor. Examples of the material for the insulating layer 49 include a dielectric such as Ta₂O₅, SiO₂, or ZnO.

The first electrode 47 is connected to the upper electrode 31 via the connection wiring line 45 and the interelement connection electrode 58. In addition, the second electrode 48 is connected to the lower electrode 32 via the connection wiring line 46 and the interelement connection electrode 59.

In the present example embodiment, the first electrode 47 is provided so as to be in contact with the cover portion 70. The second electrode 48 is laminated on the cover portion 70 with the insulating layer 49 and the first electrode 47 interposed therebetween. That is, the contact area between the first electrode 47 and the cover portion 70 is larger than the contact area between the second electrode 48 and the cover portion 70. Thus, a heat transfer path (first heat transfer path) from the excitation region 21 to the cover portion 70 through the upper electrode 31, the interelement connection electrode 58, the connection wiring line 45, and the first electrode 47 enables further improved heat dissipation than a heat transfer path (second heat transfer path) from the excitation region 21 to the cover portion 70 through the lower electrode 32, the interelement connection electrode 59, the connection wiring line 46, and the second electrode 48.

Thus, the acoustic wave filter device 10D has a configuration in which the upper electrode 31 and the interelement connection electrode 58 are connected to the input terminal 61 and is thus capable of dissipating heat preferentially through the above first heat transfer path side.

The capacitor 40A includes two layers of electrodes (the first electrode 47 and the second electrode 48), but the configuration is not limited thereto. The capacitor 40A may have a configuration in which three or more layers of electrodes are laminated. In addition, the configuration of the present example embodiment may be combined with the respective configurations of Example Embodiment 2, Example Embodiment 3, and the modified example described above.

The example embodiments described above are intended to facilitate understanding of the present invention and are not intended to construe the present invention in any limiting manner. The present invention may be modified and improved without departing from the gist and scope of the present invention and includes equivalents thereof.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave filter device comprising:
a series-arm resonator connected between an input terminal and an output terminal;
a parallel-arm resonator connected between a ground terminal and a node on a path connecting the input terminal and the output terminal; and
a capacitor connected between the input terminal and the output terminal; wherein
the capacitor is connected in parallel to the series-arm resonator.

2. The acoustic wave filter device according to claim 1, further comprising:
a plurality of the series-arm resonators; wherein
the capacitor is connected in parallel to the series-arm resonator connected to the input terminal of the series-arm resonators.

3. The acoustic wave filter device according to claim 1, further comprising:
a shield electrode connected to the ground terminal; wherein
the shield electrode faces the capacitor.

4. The acoustic wave filter device according to claim 2, further comprising:
a shield electrode connected to the ground terminal; wherein
the shield electrode faces the capacitor.

5. The acoustic wave filter device according to claim 1, further comprising:
a piezoelectric layer including a first main surface and a second main surface opposite to the first main surface;
a support facing the second main surface of the piezoelectric layer; and
a cover portion facing the first main surface of the piezoelectric layer; wherein
the series-arm resonator and the parallel-arm resonator each include the piezoelectric layer, an upper electrode on the first main surface of the piezoelectric layer, and a lower electrode on the second main surface of the piezoelectric layer; and
the capacitor is located on a surface of the cover portion facing the first main surface of the piezoelectric layer.

6. The acoustic wave filter device according to claim 5, further comprising:
a first interelement connection electrode electrically connecting one end of the capacitor and one of the upper electrode and the lower electrode; and
a second interelement connection electrode electrically connecting another end of the capacitor and another of the upper electrode and the lower electrode.

7. The acoustic wave filter device according to claim 5, further comprising:
a shield electrode on an opposite side of the cover portion from the surface facing the first main surface of the piezoelectric layer; wherein
the shield electrode is located in a region overlapping the capacitor.

8. The acoustic wave filter device according to claim 5, further comprising:
a highly thermal conductive layer in a same layer as the piezoelectric layer on the support, the highly thermal conductive layer having a thermal conductivity higher than a thermal conductivity of the piezoelectric layer; wherein
the piezoelectric layer is located at least in a region overlapping an excitation region in which the lower electrode, the piezoelectric layer, and the upper electrode are laminated; and
the highly thermal conductive layer is located in a region around the excitation region.

9. The acoustic wave filter device according to claim 2, further comprising:
a piezoelectric layer including a first main surface and a second main surface opposite to the first main surface;
a support facing the second main surface of the piezoelectric layer; and
a cover portion facing the first main surface of the piezoelectric layer; wherein
the series-arm resonator and the parallel-arm resonator each include the piezoelectric layer, an upper electrode on the first main surface of the piezoelectric layer, and a lower electrode on the second main surface of the piezoelectric layer; and
the capacitor is located on a surface of the cover portion facing the first main surface of the piezoelectric layer.

10. The acoustic wave filter device according to claim 9, further comprising:
a first interelement connection electrode electrically connecting one end of the capacitor and one of the upper electrode and the lower electrode; and
a second interelement connection electrode electrically connecting another end of the capacitor and another of the upper electrode and the lower electrode.

11. The acoustic wave filter device according to claim 9, further comprising:
a shield electrode on an opposite side of the cover portion from the surface facing the first main surface of the piezoelectric layer; wherein
the shield electrode is located in a region overlapping the capacitor.

12. The acoustic wave filter device according to claim 9, further comprising:
a highly thermal conductive layer in a same layer as the piezoelectric layer on the support, the highly thermal conductive layer having a thermal conductivity higher than a thermal conductivity of the piezoelectric layer; wherein
the piezoelectric layer is located at least in a region overlapping an excitation region in which the lower electrode, the piezoelectric layer, and the upper electrode are laminated; and
the highly thermal conductive layer is located in a region around the excitation region.

13. The acoustic wave filter device according to claim 3, further comprising:
a piezoelectric layer including a first main surface and a second main surface opposite to the first main surface;
a support facing the second main surface of the piezoelectric layer; and
a cover portion facing the first main surface of the piezoelectric layer; wherein
the series-arm resonator and the parallel-arm resonator each include the piezoelectric layer, an upper electrode on the first main surface of the piezoelectric layer, and a lower electrode on the second main surface of the piezoelectric layer; and
the capacitor is located on a surface of the cover portion facing the first main surface of the piezoelectric layer.

14. The acoustic wave filter device according to claim 13, further comprising:
a first interelement connection electrode electrically connecting one end of the capacitor and one of the upper electrode and the lower electrode; and
a second interelement connection electrode electrically connecting another end of the capacitor and another of the upper electrode and the lower electrode.

15. The acoustic wave filter device according to claim 13, further comprising:
a shield electrode on an opposite side of the cover portion from the surface facing the first main surface of the piezoelectric layer; wherein
the shield electrode is located in a region overlapping the capacitor.

16. The acoustic wave filter device according to claim 13, further comprising:
a highly thermal conductive layer in a same layer as the piezoelectric layer on the support, the highly thermal conductive layer having a thermal conductivity higher than a thermal conductivity of the piezoelectric layer; wherein
the piezoelectric layer is located at least in a region overlapping an excitation region in which the lower electrode, the piezoelectric layer, and the upper electrode are laminated; and
the highly thermal conductive layer is located in a region around the excitation region.

17. The acoustic wave filter device according to claim 5, further comprising:
a highly thermal conductive layer in a same layer as the piezoelectric layer on the support, the highly thermal conductive layer having a thermal conductivity higher than a thermal conductivity of the piezoelectric layer;
a first interelement connection electrode electrically connecting one end of the capacitor and the upper electrode; and
a second interelement connection electrode electrically connecting another end of the capacitor and the lower electrode; wherein
the piezoelectric layer is located at least in a region overlapping an excitation region in which the lower electrode, the piezoelectric layer, and the upper electrode are laminated; and
the highly thermal conductive layer is located in a region around the excitation region and is around the second interelement connection electrode.

18. The acoustic wave filter device according to claim 17, further comprising:
a connector between the cover portion and the support; and
a terminal on a surface of the cover portion opposite to the piezoelectric layer, the terminal being connected to the connector through a via passing through the cover portion; wherein
the highly thermal conductive layer is located in a region overlapping the connector.

19. The acoustic wave filter device according to claim 5, wherein the piezoelectric layer includes single-crystal lithium niobate or lithium tantalate.

20. The acoustic wave filter device according to claim 9, wherein the piezoelectric layer includes single-crystal lithium niobate or lithium tantalate.
